(19) United States
(12) Patent Application Publication
(10) Pub. No.: US 2024/0408802 A1
(43) Pub. Date: Dec. 12, 2024

(54) MOLD FOR RESIN MOLDING, RESIN MOLDING APPARATUS, AND METHOD FOR PRODUCING RESIN MOLDED ARTICLE

(71) Applicant: TOWA CORPORATION, Kyoto-shi, Kyoto (JP)

(72) Inventors: Hiroyuki SAKAGUCHI, Kyoto-shi, Kyoto (JP); Makoto TSUKIYAMA, Kyoto-shi, Kyoto (JP)

(73) Assignee: TOWA CORPORATION, Kyoto-shi, Kyoto (JP)

(21) Appl. No.: 18/702,646

(22) PCT Filed: Aug. 9, 2022
(86) PCT No.: PCT/JP2022/030366

§ 371 Date: Apr. 18, 2024

(30) Foreign Application Priority Data
Oct. 19, 2021 (JP) 2021-170709

(51) Int. Cl. B29C 45/02; B29C 45/00; B29C 45/34; B29L 7/00

(52) U.S. Cl. CPC B29C 45/02; B29C 45/34; B29C 2045/0094; B29L 2007/002

(57) ABSTRACT

The present disclosure relates to an upper die configured to hold a substrate, and a lower die configured to be clamped with the upper die and has a cavity. The lower die includes a pot that is communicably connected to a resin injection port provided on the bottom surface of the cavity, and where the resin material is contained, an injection plunger is advanced and retracted inside the pot to inject the resin material into the cavity via the resin injection port, a resin reservoir that is connected to a discharge port provided on the bottom surface of the cavity communicably, and where resin material flown out of the cavity accumulates, a suction hole that is connected to the resin reservoir and that is configured to suction the air via the resin reservoir, through the discharge port, and a switching plunger.

### TECHNICAL FIELD

The present invention relates to a molding die for resin molding, a resin molding apparatus, and a resin molded product manufacturing method.

### BACKGROUND ART

Conventionally, a pin-gate (or pin-point-gate) transfer molding method for molding resin has been disclosed, as in Patent Literature 1. With this method, a molded object is molded with resin by injecting the resin from the bottom surface of a cavity. When such a resin transfer molding method is used with vacuum molding such as that described in Patent Literature 2, the cavity is vacuumed by drawing air from the cavity before the upper die and the lower die are completely clamped.

In the pin-gate transfer molding method for molding resin, depending on the position of the gate via which the resin is injected (resin injection port), the channel along which the resin material flows inside the cavity can become quite long, and resultant molded products may end up having parts not filled with resin or voids (the resin molded products may have void-like defects).

An alternative for addressing such a concern is to use a less viscous resin material. With a less viscous resin material is used in the vacuum molding described above, however, if the upper die and the lower die are vacuumed before the upper die and the lower die are completely clamped, the molten resin material inside the pot may flow out through the gate and into the cavity, and cause defects, e.g., by molten resin material becoming attached to a surface to be exposed.

### CITATION LIST

### Patent Literatures

Patent Literature 1: JP 2021-62591 A
Patent Literature 2: JP 2012-204697 A

### SUMMARY OF INVENTION

### Technical Problem

The present invention has been made to address the issues described above, and a main object of the present invention is to reduce molding defects in a resin transfer molding method.

### Solution to Problem

That is, a molding die for resin molding according to the present invention includes: a first die configured to hold a molded object; and a second die configured to be clamped with the first die and having a cavity, wherein the second die includes: a pot that is communicably connected to a resin injection port provided on a bottom surface of the cavity, and where a resin material is contained; an injection plunger that is advanced and retracted inside the pot to inject the resin material into the cavity via the resin injection port; a resin reservoir that is communicably connected to a discharge port provided on the bottom surface of the cavity where the resin material flown out of the cavity accumulates; a suction hole that is connected to the resin reservoir and that is configured to suction air via the resin reservoir, through the discharge port; and a switching plunger that is advanced and retracted inside the resin reservoir to switch between a mode for communicably connecting the suction hole to the discharge port, and a mode for blocking the suction hole.

### Advantageous Effect of Invention

According to the present invention having the configuration described above, it is possible to reduce molding defects in the resin transfer molding method.

### BRIEF DESCRIPTION OF DRAWINGS

FIG. 1 is a cross-sectional view schematically illustrating a configuration of a resin molding apparatus according to an embodiment of the present invention.

FIG. 2(a) is a plan view schematically illustrating a configuration of a substrate according to the embodiment, and FIG. 2(b) is a plan view schematically illustrating a configuration of a lower die.

FIG. 3(a) is a plan view schematically illustrating a specific configuration of a pressing channel member according to the embodiment, and FIG. 3(b) is a perspective view thereof.

FIG. 4 is a cross-sectional view schematically illustrating a peripheral structure of a pressing channel member during clamping in the same embodiment.

FIG. 5 is a schematic cross-sectional view for explaining a resin molded product manufacturing method according to the embodiment.

FIG. 6 is a schematic cross-sectional view for explaining the resin molded product manufacturing method according to the embodiment.

FIG. 7 is a schematic cross-sectional view for explaining the resin molded product manufacturing method according to the embodiment.

FIG. 8 is a schematic cross-sectional view for explaining the resin molded product manufacturing method according to the embodiment.

FIG. 9 is a schematic cross-sectional view for explaining the resin molded product manufacturing method according to the embodiment.

FIG. 10 is a schematic cross-sectional view for explaining the resin molded product manufacturing method according to the embodiment.

FIG. 11 is a cross-sectional view schematically illustrating a configuration of a molding die for resin molding according to a modified embodiment.

FIG. 12 is a plan view schematically illustrating a configuration of a lower die according to a modified embodiment.

FIG. 13 is a cross-sectional view schematically illustrating a configuration of a molding die for resin molding according to a modified embodiment.

FIG. 14 is a plan view schematically illustrating a configuration of a lower die according to a modified embodiment.

### DESCRIPTION OF EMBODIMENT

The present invention will now be explained more in detail using some examples. However, the following explanations are not intended to limit the scope of the present invention in any way.

A molding die for resin molding according to the present invention includes, as described above, a first die configured to hold a molded object; and a second die configured to be clamped with the first die and having a cavity, wherein the second die includes: a pot that is communicably connected to a resin injection port provided on a bottom surface of the cavity, and where a resin material is contained; an injection plunger that is advanced and retracted inside the pot to inject the resin material into the cavity via the resin injection port; a resin reservoir that is communicably connected to a discharge port provided on the bottom surface of the cavity and where the cavity where the resin material flown out of the cavity accumulates; a suction hole that is connected to the resin reservoir and that is configured to suction air via the resin reservoir, through the discharge port; and a switching plunger that is advanced and retracted inside the resin reservoir to switch between a mode for communicably connecting the suction hole to the discharge port, and a mode for blocking the suction hole.

With this molding die for resin molding, because the discharge port is provided on the bottom surface of the cavity of the second die, and the resin reservoir communicably connected to the discharge port is provided, the air remaining inside the cavity can be pushed out into the resin reservoir at the time of injecting resin, and molding defects such as formation of parts not filled with resin or voids in resin molded products can be reduced.

In addition, because the suction hole for suctioning the air inside the cavity is connected to the resin reservoir, it is possible to vacuum the air inside of the cavity and depressurize the cavity, while the first die and the second die are clamped to each other. Therefore, even if the molten resin material passes through the resin injection port and enters the cavity, as a result of vacuuming the air, because the upper and lower dies are clamped to each other, it is possible to reduce defects, such as molten resin material becoming attached to unintended parts. As a result, it is possible to reduce the defects in the resin molded products. For example, for the transfer molding for exposed die molding, in which a molded object is molded with the surface of a chip disposed on the molded object exposed, it is possible to vacuum the air inside the cavity and to depressurize the cavity while protecting the surface to be exposed on the chip of the molded object. Therefore, it is possible to reduce defects such as molten resin material becoming attached to the surface to be exposed on the chip (chip flash).

Furthermore, because the switching plunger switches between a mode for communicably connecting the suction hole to the resin reservoir to the discharge port and a mode for blocking the suction hole, it is possible to prevent the resin material from flowing through the suction hole and getting into the suction channel on the downstream side of the suction hole.

In order to reduce molding defects by evenly spreading the resin material across the cavity, the resin injection port and the discharge port are preferably provided on an outer periphery of the bottom surface of the cavity, and provided at positions symmetrical to each other with respect to a center of the bottom surface of the cavity.

In order to associate the operation of the injection plunger injecting the resin material to the switching operation of the switching plunger, the injection plunger and the switching plunger are preferably advanced and retracted in a manner associated with each other.

As a specific embodiment, preferably, the switching plunger switches from the mode for communicably connecting the suction hole to the discharge port, to the mode for blocking the suction hole, in a manner associated with an operation of the injection plunger injecting the resin material, and then switches to a mode for pressing the resin material inside the cavity, together with the injection plunger. By causing the switching plunger to press the resin material inside the cavity with the injection plunger, it is possible to further reduce parts not filled with resin or voids in resin molded products.

As a specific embodiment of the second die, the second die preferably includes an intermediate plate having the cavity, and provided with the resin injection port and the discharge port, and a lower plate provided with the pot, the resin reservoir, and the suction hole. By separating the second die into the intermediate plate and the lower die, various types of second dies can be achieved depending on the type of the molded object.

In order to enable resin to be molded suitably depending on the type of the molded object, preferably, the resin injection port is provided in a plurality, the plurality of resin injection ports are connected to the pot via a resin supply channel, or the discharge port is provided in plurality, and the plurality of discharge ports are connected to the resin reservoir via a resin discharge channel.

In order to increase the thickness of the resin molded on the molded object or to mold a molded object having a large size, it is necessary to increase the amount of the resin material to be injected. For this purpose, preferably, the pot is provided in plurality, and the plurality of pots are connected to the resin injection port via a resin supply channel. In addition, in order to improve the quality of the molded object, preferably, the resin reservoir is provided in plurality, and the plurality of resin reservoirs are connected to the discharge port by a resin discharge channel.

A resin molding apparatus including the molding die for resin molding described above is also one aspect according to the present invention.

A resin molded product manufacturing method using the molding die for resin molding described above is also one aspect according to the present invention. Specifically, a resin molded product manufacturing method according to the present invention is a resin molded product manufacturing method that uses the molding die for resin molding described above, the resin molded product manufacturing method including: a mold clamping step of clamping the first die and the second die; a depressurizing step of suctioning air through the suction hole with a vacuum pump to depressurize the cavity while the suction hole and the discharge port are communicably connected to each other; and a resin injection step of moving the injection plunger to inject the resin material into the cavity through the resin injection port, as well as moving the switching plunger to block the discharge port and the suction hole.

Preferably, the resin molded product manufacturing method further includes, before the clamping step, placing a release film having through holes at positions corresponding to the injection port and the discharge port, respectively, provided on an inner surface including a bottom surface of the cavity, and placing pressing channel members for pressing peripheries of the respective through holes of the release film during clamping, and for forming communication channels communicably connecting the respective through holes to the cavity.

With this configuration, it is possible to remove the resin molded product easily from the cavity, and to prevent damages of the resin molded product at the time of releasing from the die. Furthermore, because the pressing channel members are pressed against the peripheries of the respective through holes in the release film, it is possible to prevent the molten resin material from entering the gap between the release film and the bottom surface of the cavity. Furthermore, because each of the pressing channel members has a communication channel communicably connecting the through holes of the release film to the cavity, the flow of the molten resin material from the resin injection port to the discharge port is not obstructed, either.

### Each Embodiment of Present Invention

One embodiment of a resin molding apparatus according to the present invention will now be explained with reference to some drawings. Note that all of the drawings described below are schematic representations, with some omissions and exaggerations made as appropriate, to facilitate understanding. The same elements are denoted by the same reference numerals, and the descriptions thereof will be omitted as appropriate.

### <Overall Configuration of Resin Molding Apparatus>

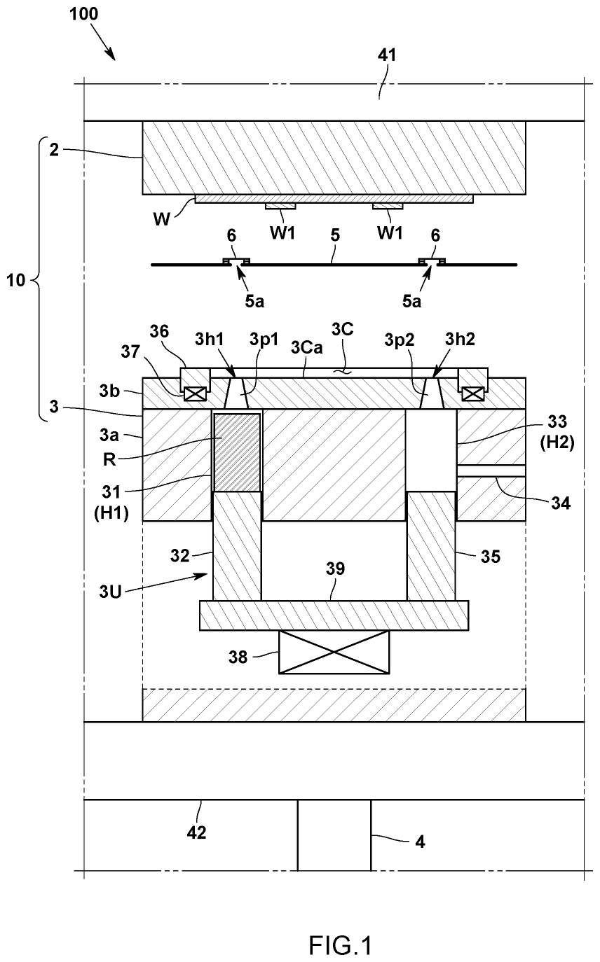

As illustrated in FIG. 1, a resin molding apparatus 100 according to the embodiment is a resin molding apparatus using a transfer molding method with the use of a pin gate. The resin molding apparatus 100 is for molding a substrate W having an electronic component such as a semiconductor chip (hereinafter, also referred to as a chip W1) mounted thereon, with a resin, as an example of a molded object, and uses thermosetting resin having a cylindrical tablet-like shape as a resin material R.

Examples of the “substrate” include a semiconductor substrate such as a silicon wafer, a lead frame, a printed wiring board, a metal substrate, a resin substrate, a glass substrate, and a ceramic substrate. The substrate W may be a carrier used in fan-out wafer-level packaging (FOWLP) and fan-out panel-level packaging (FOPLP).

Furthermore, the substrate W may be provided with wirings, or has not been provided with wirings.

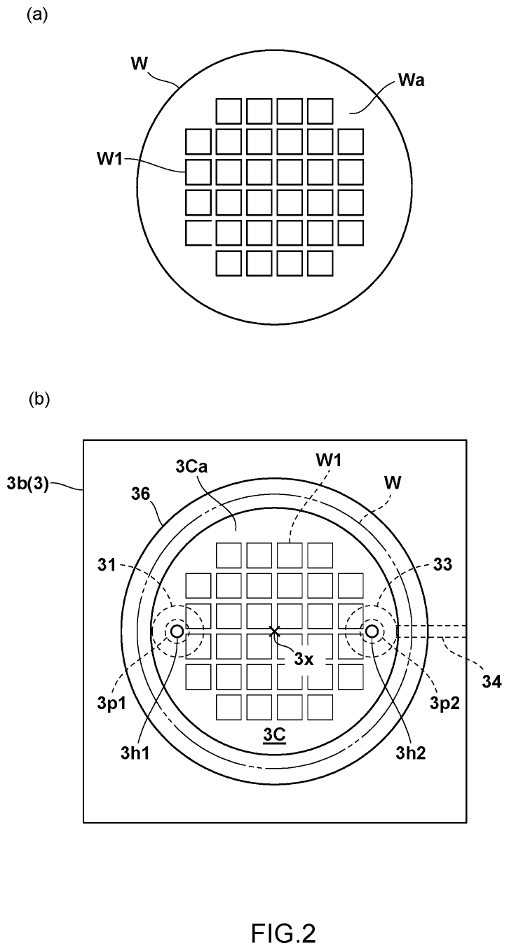

In the embodiment, as illustrated in FIG. 2(a), the substrate W has a circular shape, as an example, in a plan view, and a plurality of chips W1, all of which are identical and each of which has a rectangular shape in a plan view, are vertically and horizontally arranged at equal pitches, in a manner protruding on a front surface Wa. After resin molding, the substrate W is cut and diced into chips W1. However, for example, if the substrate W is for the use in FOWLP, FOPLP, or the like, the substrate W may be separated from the sealing resin after molding, without being diced. Note that the substrate W may have various shapes such as a rectangular shape in a plan view.

Specifically, as illustrated in FIG. 1, the resin molding apparatus 100 includes a resin-molding die 10 including an upper die 2 as a first die and a lower die 3 as a second die, and a mold clamping mechanism 4 for clamping the resin-molding die 10 (the upper die 2 and the lower die 3).

The upper die 2 is fixed to the bottom surface of an upper fixed platen 41, and the lower die 3 is fixed to the top surface of a movable platen 42. The mold clamping mechanism 4 moves the movable platen 42 vertically, to clamp or to unclamp the upper die 2 and the lower die 3. As the mold clamping mechanism 4, it is possible to use a linear motion driving mechanism that uses a ball screw mechanism to convert the rotation of a servomotor or the like into a linear movement and to communicate the linear movement to the movable platen 42, or a linkage mechanism that uses a linkage mechanism such as a toggle linkage to transmits power from a power source such as a servomotor to the movable platen 42.

### <Resin-Molding Die 10>

The resin-molding die 10 includes, specifically, as described above, the upper die 2 that holds the substrate W and the lower die 3 having a cavity 3C, as illustrated in FIG. 1.

The upper die 2 is configured to suction to hold the substrate W, and has a plurality of suction holes (not illustrated) on a bottom surface of the upper die 2 (a surface facing the lower die 3). A vacuum pump or the like generates a negative pressure in these suction holes, so that the rear surface of the substrate W is suctioned to and held by the upper die 2. The substrate W is then conveyed to the upper die 2 by a conveyance mechanism (loader), not illustrated. A heating unit such as a heater (not illustrated) is embedded in the upper die 2, and the upper die 2 is usually heated to about 180° C. by the heating unit during resin molding.

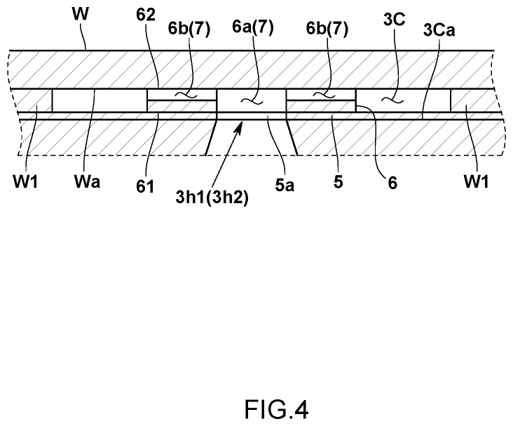

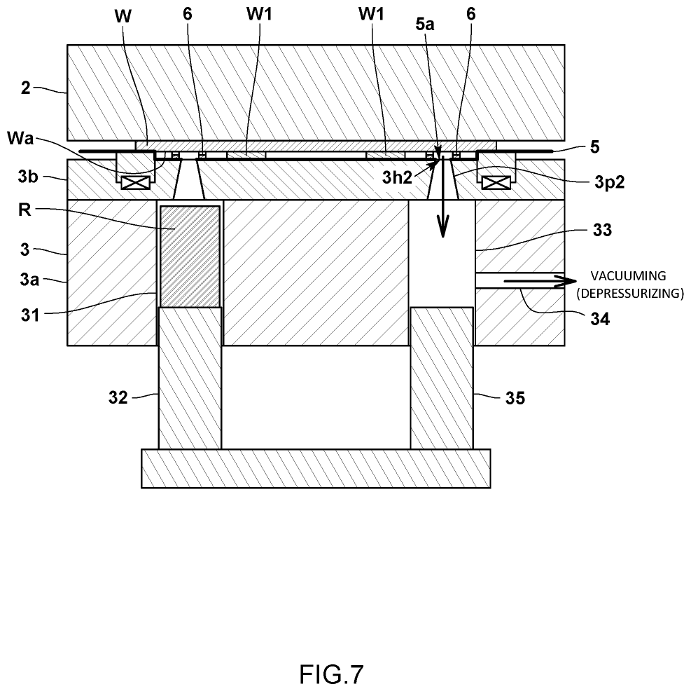

The lower die 3 has the cavity 3C for accepting the chips W1 on the substrate W held onto the upper die 2 at the time of clamping. As illustrated in FIG. 2(b), the cavity 3C has a contour slightly smaller than the substrate W. In the embodiment, the depth of the cavity 3C is substantially equal to the thickness of the chip W1. These sizes are set so that, at the time of clamping, the top surface of the chip W1 comes into close contact with a bottom surface 3Ca of the cavity 3C or a release film 5, when there is any release film 5 (see FIGS. 4 and 7). In this manner, the resin material R does not rise above the top surface of the chip W1, and only lateral peripheral surfaces of the chips W1 are covered by the resin material R. Therefore, after the resin molding, the top surface of the chip W1 remains exposed. The “top surface” of the chip W1 herein is a surface facing the opposite side of the substrate W, that is, the surface facing the release film 5 during the resin molding.

At the time of clamping, an outer rim of the cavity 3C comes into close contact with the peripheral edge of the substrate surface Wa, the top opening of the cavity 3C is closed by the substrate W, and the chips W1 on the substrate W is accepted into the cavity 3C (see FIGS. 4 and 7).

The lower die 3 according to the embodiment includes, as illustrated in FIG. 1, a lower plate 3a, and an intermediate plate 3b that is separably mounted on the top surface of the lower plate 3a. The cavity 3C is provided on the top surface of the intermediate plate 3b (the surface facing the upper die 2), and a lift-up mechanism, not illustrated, lifts the intermediate plate 3b above the top surface of the lower plate 3a.

As illustrated in FIG. 1, the lower die 3 according to the embodiment includes: a pot 31 that is communicably connected to a resin injection port 3h1 provided on the bottom surface 3Ca of the cavity 3C, and where the resin material R is contained; an injection plunger 32 that is advanced and retracted inside the pot 31 to inject the resin material R into the cavity 3C via the resin injection port 3h1; a resin reservoir 33 that is communicably connected to a discharge port 3h2 provided on the bottom surface 3Ca of the cavity 3C and where the resin material R flown out of the cavity 3C accumulates; a suction hole 34 that is connected to the resin reservoir 33 and that is configured to suction the air via the resin reservoir 33, through the discharge port 3h2; and a switching plunger 35 that is advanced and retracted inside the resin reservoir 33 to switch between a mode for communicably connecting the suction hole 34 to the discharge port 3h2, and a mode for blocking the suction hole 34.

The pot 31, the resin reservoir 33, and the suction hole 34 are provided to the lower plate 3a, and the resin injection port 3h1 and the discharge port 3h2 are provided to the intermediate plate 3b.

The lower plate 3a has two through holes H1, H2 penetrating through the lower plate 3a in the thickness direction. The one through hole H1 serves as the pot 31 for containing the resin material R, and the other through hole H2 serves as the resin reservoir 33 where the resin material R flown out of the cavity 3C accumulates. Each of the through holes H1, H2 forming the pot 31 and the resin reservoir 33, respectively, has a circular shape the cross section of which has a constant diameter across the thickness direction of the lower plate 3a. The resin material R is conveyed and placed into the pot 31 of the lower plate 3a by a resin material conveyor mechanism, not illustrated. A heating unit such as a heater (not illustrated) is embedded in the lower plate 3a, and heats the lower plate 3a generally to a temperature of about 180° C. during resin molding.

The lower plate 3a has the suction hole 34 that is connected to the resin reservoir 33, the suction hole 34 being a hole through which a suction mechanism (not illustrated) such as an external vacuum pump draws out the air. One end of the suction hole 34 opens to the inner circumferential surface of the resin reservoir 33, and the other end opens to a lateral side surface of the lower plate 3a.

The intermediate plate 3b is provided with a side surface member 36 forming the inner circumferential surface of the cavity 3C. The side surface member 36 is supported by an elastic member 37 in a manner enabled to move up and down. Apart of the top surface of the intermediate plate 3b, the part being on the inner side of the side surface member 36, serves as the bottom surface 3Ca of the cavity 3C. The top surface of the side surface member 36 serves as the outer rim of the cavity 3C, and comes into close contact with the peripheral edge of the substrate surface Wa at the time of clamping, or comes into close contact with the periphery via the release film 5 when the release film 5 is used.

The intermediate plate 3b also has a first channel 3p1 through which the resin material R pushed out of the pot 31 flows. The first channel 3p1 is provided at a position enabling the resin material R pushed out of the pot 31 to be introduced into the cavity 3C. The first channel 3p1 penetrates through the intermediate plate 3b in the thickness direction, and opens to the bottom surface 3Ca of the cavity 3C. This opening serves as the resin injection port 3h1. The first channel 3p1 according to the embodiment has a circular cross section tapered toward the bottom surface 3Ca of the cavity 3C.

The intermediate plate 3b also has a second channel 3p2 through which the resin material R flown out of the cavity 3C flows. The second channel 3p2 is provided at a position enabling the resin material R flown out of the cavity 3C to be introduced into the resin reservoir 33. The second channel 3p2 penetrates through the intermediate plate 3b in the thickness direction, and opens to the bottom surface 3Ca of the cavity 3C. This opening serves as the discharge port 3h2. In the same manner as the first channel 3p1, the second channel 3p2 according to the embodiment has a circular cross section tapered toward the bottom surface 3Ca of the cavity 3C.

These resin injection port 3h1 and discharge port 3h2 are provided on the outer periphery of the bottom surface 3Ca of the cavity 3C, as illustrated in FIG. 2(b), T, and are provided at positions symmetrical to each other with respect to a center 3x of the bottom surface 3Ca of the cavity 3C. In the embodiment, the resin injection port 3h1 and the discharge port 3h2 on the bottom surface 3Ca of the cavity 3C are provided at positions facing areas of the substrate W, the areas being on the outer side of the area where the chips are mounted, and are provided at positions symmetrical to each other with respect to the center 3x of the bottom surface 3Ca of the cavity 3C. The diameter of the opening of the resin injection port 3h1 is the equal to or larger than the diameter of the opening of the discharge port 3h2.

As illustrated in FIG. 1, the injection plunger 32 is inserted into the through hole H1 forming the pot 31, from the bottom end of the through hole H1, and is advanced and retracted (moved up and down) by a plunger driving unit 38. The injection plunger 32 has a columnar shape the outer diameter of which is set equal to the inner diameter of the pot 31, and is slidably fitted into the pot 31 without looseness (with substantially no gap). As the plunger driving unit 38, for example, a combination of a servo motor and a ball screw mechanism, or a combination of an air cylinder or a hydraulic cylinder and a rod may be used.

The switching plunger 35 is inserted into the through hole H2 forming the resin reservoir 33, from the bottom end of the through hole H2, and is advanced and retracted (moved up and down) by the plunger driving unit 38. The switching plunger 35 has a columnar shape the outer diameter of which is set equal to the inner diameter of the resin reservoir 33, and is slidably fitted into the resin reservoir 33, without any looseness. As will be described later, the switching plunger 35 is configured to close the suction hole 34 so as to block the communication between the discharge port 3h2 and the suction hole 34, before the resin material R, having been injected by the injection plunger 32 into the cavity 3C, reaches the discharge port 3h2. In other words, the suction hole 34 is provided at a position that can be closed by the switching plunger 35 before the resin material R reaches the discharge port 3h2.

In the embodiment, the injection plunger 32 and the switching plunger 35 are configured to be advanced and retracted in a manner associated each other, by the plunger driving unit 38.

The injection plunger 32 and the switching plunger 35 together form a plunger unit 3U, by being provided on a common base member 39. The plunger unit 3U is enabled to be advanced and retracted by the single plunger driving unit 38, so that the injection plunger 32 and the switching plunger 35 are advanced and retracted in a manner associated with each other. In addition, because the single plunger driving unit 38 is used to cause the injection plunger 32 and the switching plunger 35 to operate in a manner associated with each other, it is possible to simplify the configuration of the apparatus.

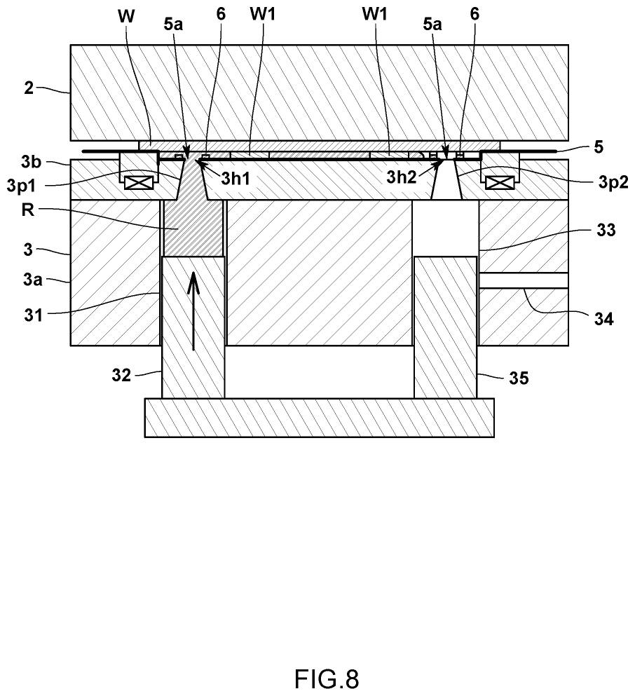

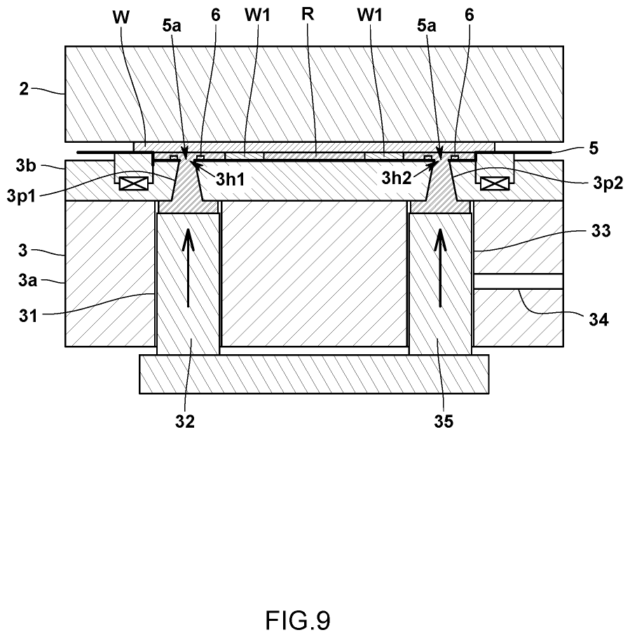

Specifically, the switching plunger 35 is at a position where the discharge port 3h2 and the suction hole 34 communicate with each other before the resin material R is injected by the injection plunger 32 (during the stage at which the air is drawn) (see FIG. 7). The switching plunger 35 as well as the injection plunger 32 rise as the injection plunger 32 starts injecting the resin material R. Then, before the resin material R injected by the injection plunger 32 reaches the discharge port 3h2 of the cavity 3C, the switching plunger 35 moves to a level above the suction hole 34 inside the resin reservoir 33, and closes the suction hole 34, so as to block the communication between the discharge port 3h2 and the suction hole 34 (see FIG. 8). The switching plunger 35 keep rising thereafter with the injection plunger 32, pressing the resin material R into the cavity 3C with the injection plunger 32 (see FIG. 9).

### <Release Film 5>

As illustrated in FIGS. 1 and 4, the resin molding apparatus 100 further includes a release film 5 and a film supply mechanism (not illustrated) that supplies the release film 5 onto the top surface of the intermediate plate 3b.

The release film 5 is disposed in close contact with the inner surface of the cavity 3C, including the bottom surface 3Ca. The release film 5 is interposed between the inner surface of the cavity 3C and the injected resin material R so that the resin material R peels off from the cavity 3C easily, after the molding cures inside the cavity 3C. Because the material and the like of the release film 5 are known, descriptions thereof will be omitted herein. A film appress mechanism, not illustrated, brings the release film 5 into close contact with the inner surface of the cavity 3C. The film appress mechanism includes a plurality of suction holes provided on the inner surface of the cavity 3C and/or the top surface of the outer periphery of the cavity 3C, and a vacuum pump that generates a negative pressure inside these suction holes.

The release film 5 according to the embodiment is configured not to close the resin injection port 3h1 and the discharge port 3h2 formed on the bottom surface 3Ca of the cavity 3C. Specifically, the release film 5 has through holes 5a at a position corresponding to the resin injection port 3h1 and the discharge port 3h2, respectively. These through holes 5a have diameters equal to or slightly larger than the opening diameters of the resin injection port 3h1 and the discharge port 3h2, respectively.

### <Pressing Channel Members 6>

As illustrated in FIGS. 1, 3, and 4, the resin molding apparatus 100 according to the embodiment further includes pressing channel members 6 each pressing a part of the release film 5 around the corresponding through hole 5a, via the substrate W, at the time of clamping, to bring the release film 5 into close contact with the bottom surface 3Ca of the cavity 3C.

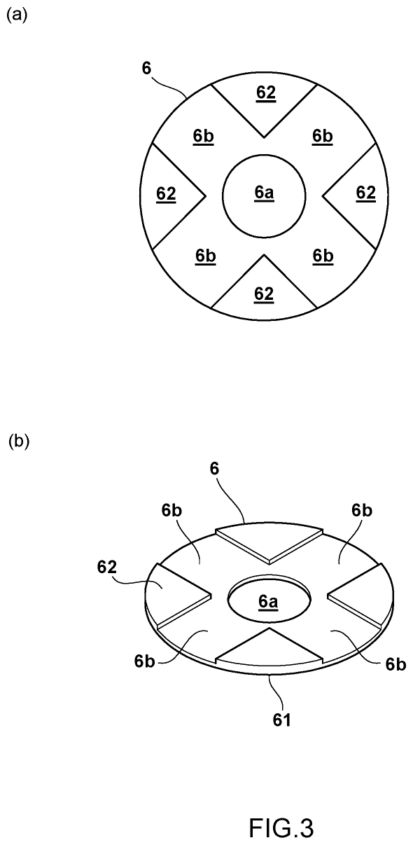

Each of the pressing channel members 6 presses the part of the release film 5 around the corresponding through hole 5a, at the time of clamping the dies, and forms the communication channel 7 that connects the through hole 5a to the cavity 3C. As particularly illustrated in FIG. 3, the pressing channel member 6 according to the embodiment has a disk-like shape with a through hole 6a at the center. The front surface of the pressing channel member 6 is flat, and the surface 61 serves as a pressing surface. The rear surface 62, by contrast, has a plurality of (four in the example herein) bottomed grooves 6b that are uniformly formed and extending radially, for example. The communication channel 7 is formed by the through hole 6a and the bottomed grooves 6b. Note that the communication channel 7 is not limited to a groove, and may be formed using an internal channel formed inside the thickness.

The thickness of the pressing channel member 6 is set substantially equal to the distance between the substrate surface Wa and the bottom surface 3Ca of the cavity 3C. This is to enable the surface 61 of the pressing channel member 6 to press the release film 5 via the substrate W, at the time of clamping, so as to bring the release film 5 into close contact with the bottom surface 3Ca of the cavity 3C, as described earlier. The thickness of the pressing channel member 6 is the size between the front surface 61 and the rear surface 62, and is also equal to the thickness of the chip W1 in the embodiment.

### <Resin Molded Product Manufacturing Method>

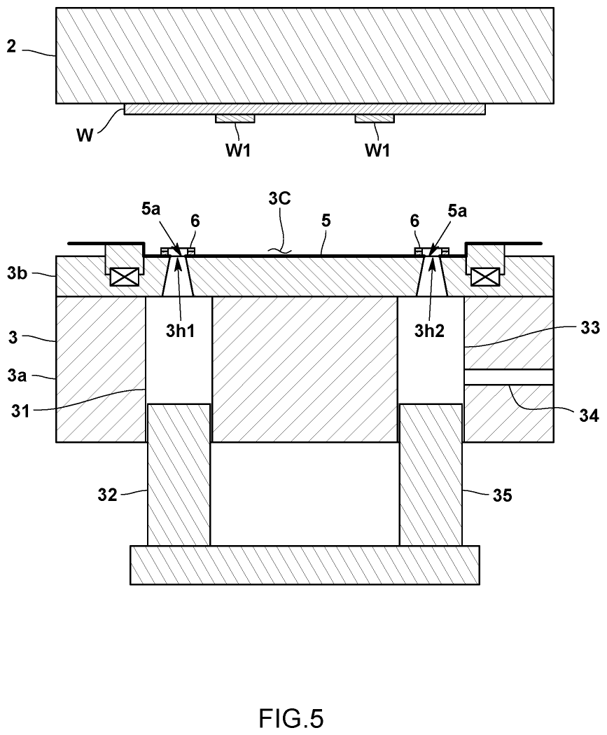

A method for manufacturing a resin molded product P (resin-molded substrate W) using the resin molding apparatus 100 (resin-molding die 10) having the configuration described above will now be explained with reference to FIGS. 5 to 10.

As illustrated in FIG. 5, with the upper die 2 and the lower die 3 separated from each other, the film supply mechanism supplies the release film 5 onto the top surface of the intermediate plate 3b resting on the lower plate 3a. The supplied release film 5 is suctioned onto the top surface of the intermediate plate 3b. A supply mechanism, not illustrated, places the pressing channel members 6 around the respective through holes 5a on the release film 5. At this time, the supply mechanism places the respective pressing channel members 6 at such positions that the through holes 6a communicate with the respective through holes 5a of the release film 5. The loader then supplies a substrate W onto the bottom surface of the upper die 2. The supplied substrate W is suctioned and held onto the bottom surface of the upper die 2, in the orientation in which the chip W1 faces the cavity 3C.

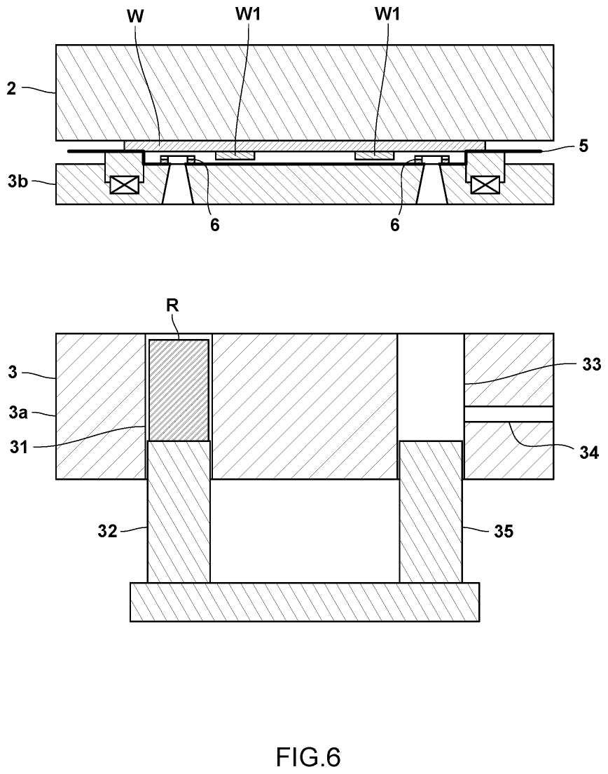

The lift-up mechanism then lifts and separates the intermediate plate 3b from the lower plate 3a, as illustrated in FIG. 6. At this time, the injection plunger 32 is set to a standby position where a solid resin material R can be charged into the pot 31, onto the tip end of the injection plunger 32. A solid resin material R is then charged into the pot 31 from above, and the heating unit provided on the lower plate 3a then causes the resin material R to melt.

The mold clamping mechanism 4 then clamps the upper die 2 and the lower die 3 (clamping step). That is, as illustrated in FIG. 7, the mold clamping mechanism 4 lifts the lower plate 3a to integrate the lower plate with the intermediate plate 3b, so that the release film 5 is nipped between the top surface of the intermediate plate 3b and the peripheral edge of the substrate surface Wa. This position corresponds to a clamping position. At this time, as described earlier, each of the pressing channel members 6 presses the periphery of the corresponding through hole 5a of the release film 5, on the pressing surface 61 thereof, to bring the release film 5 into close contact with the bottom surface 3Ca of the cavity 3C (see FIG. 4).

While the upper and lower dies are being clamped, the switching plunger 35 is at a position allowing the discharge port 3h2 and the suction hole 34 to communicate with each other (see FIG. 7). The air in the cavity 3C is then suctioned and vacuumed from the discharge port 3h2, via the resin reservoir 33 (the cavity 3C is depressurized), by a vacuum pump (not illustrated) connected to the suction hole 34 (depressurizing step). The air in the cavity 3C then passes through the communication channel 7 inside the pressing channel member 6, which is disposed around the discharge port 3h2, and is discharged through the through hole 5a of the release film 5, the discharge port 3h2, and the second channel 3p2 of the intermediate plate 3b, the resin reservoir 33, and the suction hole 34, to the outside of the lower die 3.

Once the vacuuming of the air completes, the plunger driving unit 38 raises the injection plunger 32, to inject the molten resin material R into the cavity 3C via the resin injection port 3h1 (resin injection step), as illustrated in FIG. 8. As the injection plunger 32 rises from the standby position, the molten resin material R passes through the first channel 3p1 of the intermediate plate 3b, the resin injection port 3h1, and the through hole 5a of the release film 5, and further passes through the communication channel 7 of the pressing channel member 6, to flow into the cavity 3C.

In a manner associated with the rising injection plunger 32, the switching plunger 35 also rises inside the resin reservoir 33. Before the resin material R having been injected into the cavity 3C by the injection plunger 32 reaches the discharge port 3h2, the switching plunger 35 blocks the discharge port 3h2 from the suction hole 34, that is, the switching plunger 35 blocks the suction hole 34, as illustrated in FIG. 8.

When the injection plunger 32 and the switching plunger 35 are raised, as illustrated in FIG. 9, both the injection plunger 32 and the switching plunger 35 also press the resin material R inside the cavity 3C, by applying pressure. In this configuration, the cavity 3C is filled with the molten resin material R. By waiting for time required for the molten resin material R to cure while heating, the resin material R is cured and solidified.

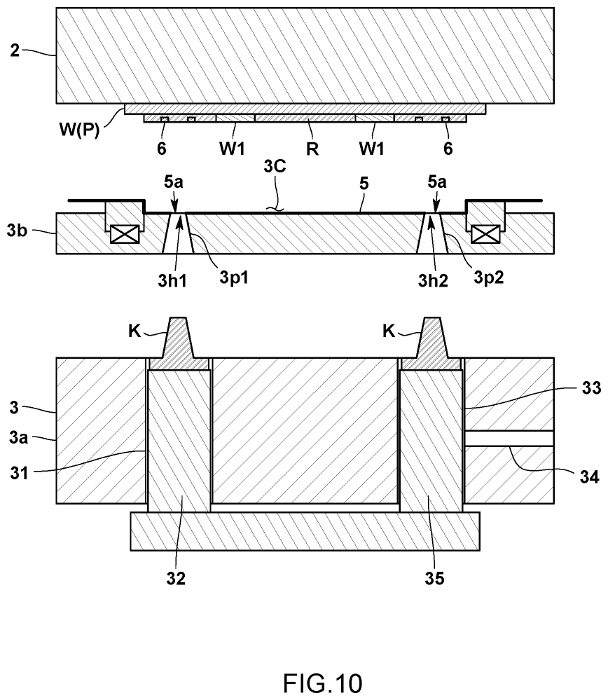

The mold clamping mechanism 4 then lowers the lower die 3 (the lower plate 3a and the intermediate plate 3b) to open the die, as illustrated in FIG. 10. At this time, residual resin K (cull) remaining inside the first channel 3p1 and the second channel 3p2 is stripped away from the substrate W. An unloader, not illustrated, then removes the resin molded substrate W (resin molded product P) from the upper die 2, and the resin molded substrate W is conveyed and stored in a substrate storage (not illustrated). By causing the lift-up mechanism to separate the intermediate plate 3b from the lower plate 3a, the residual resin K is taken out and discarded.

### Advantageous Effects Achieved by Embodiment

With the resin molding apparatus 100 according to the embodiment, because the discharge port 3h2 is provided on the bottom surface 3Ca of the cavity 3C of the lower die 3, and the resin reservoir 33 communicably connected to the discharge port 3h2 is provided, the air remaining inside the cavity 3C can be pushed out into the resin reservoir 33 at the time of injecting resin, and molding defects such as formation of parts not filled with resin or voids in the resin molded product P can be reduced.

In addition, because the suction hole 34 for suctioning the air inside the cavity 3C is connected to the resin reservoir 33, it is possible to vacuum the air inside of the cavity 3C and depressurize the cavity 3C, while the upper die 2 and the lower die 3 are clamped to each other. Therefore, even if the molten resin material R passes through the resin injection port 3h1 and enters the cavity 3C, as a result of vacuuming the air, because the upper and lower dies are clamped to each other, it is possible to reduce defects, such as molten resin material R becoming attached to unintended parts. As a result, it is possible to reduce the defects in the resin molded products P For example, for the transfer molding for exposed die molding, in which the substrate W is molded with the surface of a chip W1 disposed thereon exposed, it is possible to vacuum the air inside the cavity 3C and to depressurize the cavity 3C while protecting the surface (top surface) of the chip W1 of the substrate W to be exposed. Therefore, it is possible to reduce defects such as the molten resin material R becoming attached to the surface of the chip W1 to be exposed (chip flash).

Furthermore, because the switching plunger 35 is used to switch between a mode for communicably connect the suction hole 34 to the resin reservoir 33 to the discharge port 3h2, and a mode for blocking the suction hole 34, it is possible to prevent the resin material R from flowing into the suction hole 34, and getting into the suction channel that is on the downstream of the suction hole 34.

### Other Modifications of Present Invention

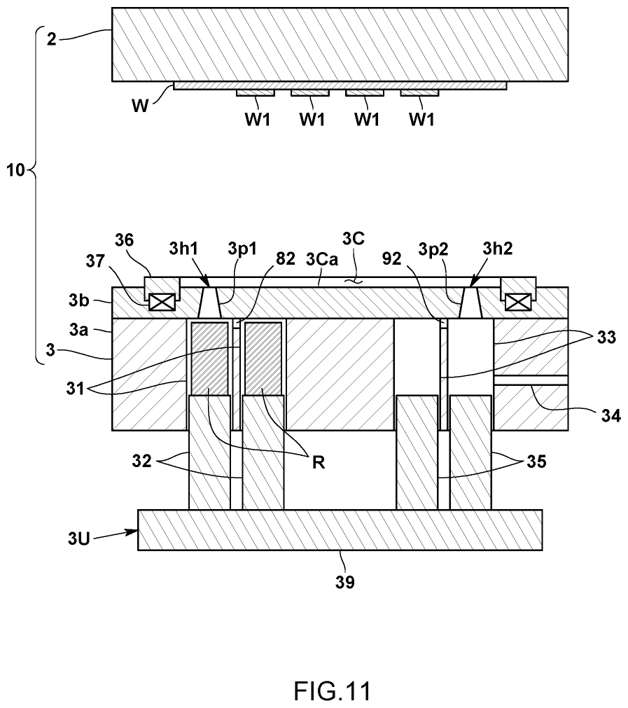

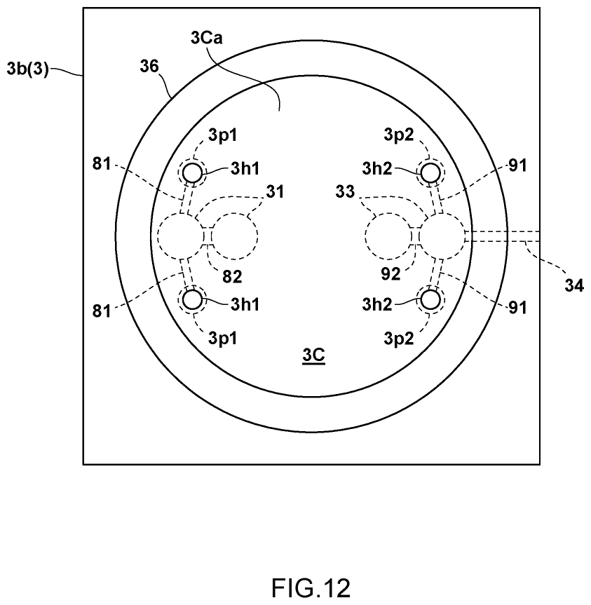

For example, it is also possible for the resin injection port 3h1 to be provided in plurality, and for the plurality of resin injection ports 3h1 to be connected to the pot 31 via a first resin supply channel 81; or for the discharge port 3h2 to be provided in plurality, and for the plurality of discharge ports 3h2 to be connected to the resin reservoir 33 via a first resin discharge channel 91, as illustrated in FIGS. 11 and 12. The first resin supply channel 81 and the first resin discharge channel 91 may be provided to the lower plate 3a or the intermediate plate 3b. As described above, it is preferable for the plurality of resin injection ports 3h1 or the plurality of discharge ports 3h2 to be formed at a position symmetric to one another, with respect to the center of the bottom surface 3Ca of the cavity 3C.

It is also possible for the pot 31 to be provided in plurality, and for the plurality of pots 31 to be connected to each other via a second resin supply channel 82, and to be connected to the resin injection ports 3h1 via the first resin supply channels 81, as illustrated in FIGS. 11 and 12. It is also possible for the resin injection port 3h1 to be provided in plurality, as illustrated in FIG. 12, or for only one resin injection port 3h1 to be provided and connected to one of the plurality of pots 31 via the first channel 3p1 (not via the first resin supply channel 81) (see FIG. 2(b)). It is also possible for the resin reservoir 33 to be provided in plurality, and for the plurality of resin reservoirs 33 to be connected to each other via a second resin discharge channel 92, and to be connected to the discharge port 3h2 via the first resin discharge channel 91. It is also possible for the discharge port 3h2 to be provided in plurality, as illustrated in FIG. 12, or for only one discharge port 3h2 to be provided and connected to one of the plurality of resin reservoirs 33 via the second channel 3p2 (not via the first resin discharge channel 91) (see FIG. 2(b)). The second resin supply channel 82 and the second resin discharge channel 92 may be provided to the lower plate 3a or the intermediate plate 3b. In the configuration including the plurality of the resin reservoirs 33, the suction hole 34 may be connected to any one of the resin reservoirs 33 or be connected to the plurality of resin reservoirs 33. Also in this configuration, in the same manner as in the embodiment described above, the injection plungers 32 and the switching plungers 35 may be moved in a manner associated with each other. At this time, in order to simplify the configuration in which the injection plungers 32 and the switching plungers 35 together form a unit and are caused to operate in a manner associated with each other, it is preferable for the plurality of pots 31 and the plurality of resin reservoirs 33 to be arranged along one straight line in a plan view. With the configuration including the plurality of pots 31 as described above, the amount of the resin can be increased, so that it is possible to cope with a product with a thick resin or with a large substrate.

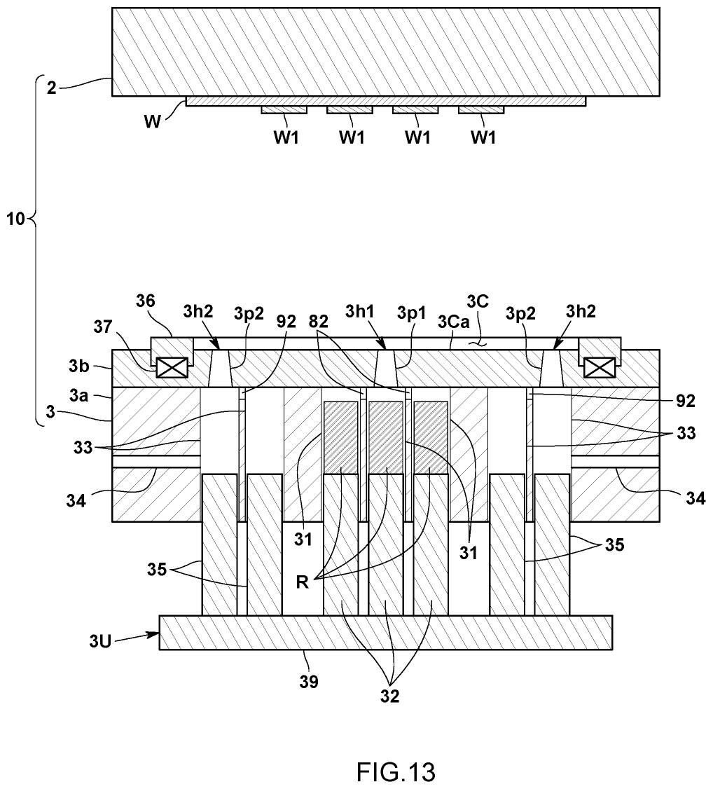

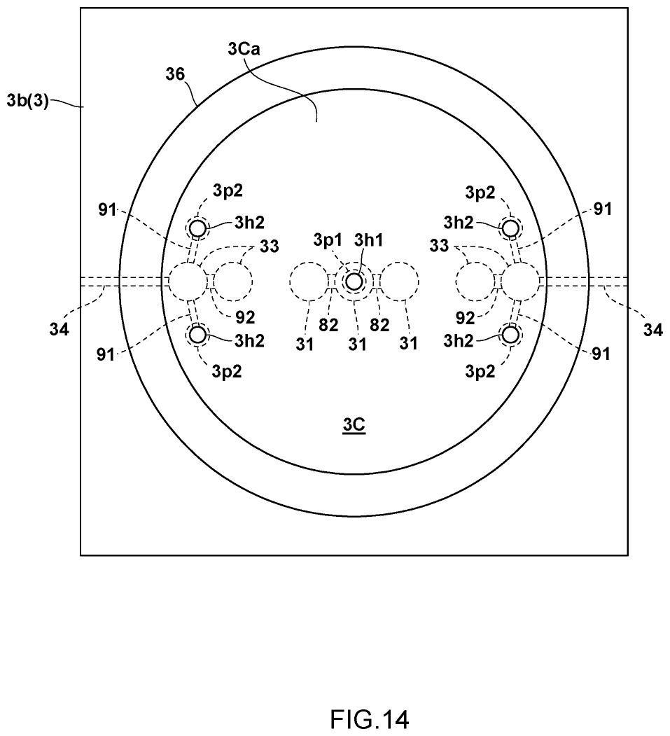

Furthermore, as illustrated in FIGS. 13 and 14, the resin injection port 3h1 may be formed in the central portion of the bottom surface 3Ca of the cavity 3C, and the plurality of discharge ports 3h2 may be formed along the outer periphery of the bottom surface 3Ca of the cavity 3C. Such a plurality of discharge ports 3h2 may be connected to the resin reservoir 33 via the first resin discharge channels 91. The plurality of discharge ports 3h2 are also preferably formed at symmetrical positions with respect to the resin injection port 3h1. The first resin discharge channel 91 may be provided in lower plate 3a or intermediate plate 3b. With this configuration, it is possible to efficiently inject and mold the resin on a large substrate W.

A plurality of pots 31 may be provided correspondingly to one resin injection port 3h1, and the plurality of pots 31 may be connected to the one resin injection port 3h1 via the second resin supply channels 82, respectively. It is also possible for the resin reservoir 33 to be provided in plurality, and for the plurality of resin reservoirs 33 to be connected to each other via a second resin discharge channel 92, and to be connected to the discharge port 3h2 via the first resin discharge channel 91. As illustrated in FIG. 14, the discharge port 3h2 may be provided in plurality, or only one discharge port 3h2 may be provided and connected to one of the plurality of resin reservoirs 33 via the second channel 3p2 (see FIG. 2(b)). The second resin supply channel 82 and the second resin discharge channel 92 may be provided to the lower plate 3a or the intermediate plate 3b. In the configuration including a plurality of resin reservoirs 33 for one discharge port 3h2, the suction hole 34 may be connected to any one of the resin reservoirs 33 or may be connected to the plurality of resin reservoirs 33. In this configuration, too, in the same manner as in the embodiment described above, the injection plungers 32 and the switching plungers 35 can be moved in a manner associated with each other. At this time, the plurality of pots 31 and the plurality of resin reservoirs 33 are preferably arranged on one straight line in a plan view.

The injection plunger and the switching plunger according to the embodiment described above together form a unit and are caused to operate in a manner associated with each other. However, it is also possible to the plunger driving units provided correspondingly to the injection plunger 32 and the switching plunger 35, respectively, not forming a unit, and to cause the injection plunger 32 and the switching plunger 35 to operate in a manner associated with each other through controlling of the plunger driving units, e.g., via sequence control. For example, it is conceivable to raise the switching plunger 35 to block the communication between the discharge port 3h2 and the suction hole 34 after a predetermined time has elapsed from when the injection plunger 32 starts injecting the resin material R, or after the injection plunger 32 has reached a predetermined position. The timing at which the switching plunger 35 is raised to block the communication between the discharge port 3h2 and the suction hole 34 is not particularly limited, as long as the timing arrives before the resin reaches the suction hole 34.

Although the pressing channel members 6 are placed on the release film 5 as single members separated from the substrate W, it is possible to provide the pressing channel members 6 in a manner bonded to the substrate W in advance, or to be provided integrally with the substrate W. It is also possible to supply a release film 5 having the pressing channel members 6 attached thereto in advance onto the lower die 3.

Each of the pressing channel member 6 may have a rectangular plate-like shape or a polygonal plate-like shape, instead of a disk-like shape.

It is also possible for the pressing channel members 6 not to be independent bodies, but the pressing channel member 6 may include a plurality of pressing elements disposed around the respective through holes 5a, in a manner spaced apart from each other, for example. In this case, the space between the pressing elements provides the communication channel 7.

As for the release film 5, the through holes 5a may be punched in advance, as in the embodiment described above, or the release film 5 may be placed on the intermediate plate 3b and suctioned, and then punched correspondingly to the positions of the resin injection port 3h1 and the discharge port 3h2, respectively.

The method for manufacturing a resin molded product P is also not limited to the embodiment described above, and the order of the steps included therein may be switched. As another example, it is also possible not suction the release film 5, and to only press the peripheries of the through holes 5a with the pressing channel members 6, respectively. With such a configuration, too, it is possible to bring the release film 5 into close contact with the inner surface of the cavity 3C, by the pressure for filling the resin material R.

Although, in the embodiment described above, the cavity 3C is provided only in the lower die 3, it is also possible to provide the cavity 3C in the upper die 2, too, and to mold the substrate W by injecting resin onto both of the front and rear surfaces of the substrate W.

The molded object is not limited to the substrate W provided with the chip W1, and the manufacturing method can also be used for molding of only the resin material R inside the cavity 3C.

The present invention is also applicable not only to molding dies 10 that move in vertical directions but also to molds that moves back and forth horizontally or in any other opposing directions.

In addition, the present invention is not limited to the embodiment described above, and it should be needless to say that various modifications may be made within the scope not departing from the gist of the present invention.

### INDUSTRIAL APPLICABILITY

According to the present invention, it is possible to reduce molding defects in the resin transfer molding method.

### REFERENCE SIGNS LIST

100 resin molding apparatus
W substrate (molded object)
P resin-molded product
R resin material
molding die for resin molding
2 upper die (first die)
3 lower die (second die)
3C cavity
3Ca bottom surface of cavity
3x center of bottom surface of cavity
3h1 resin injection port
3h2 discharge port
31 pot
32 injection plunger
33 resin reservoir
34 suction hole
switching plunger
3a lower plate
3b intermediate plate
4 mold clamping mechanism
release film
5a through hole
6 pressing channel member
7 communication channel
81, 82 resin supply channel
91, 92 resin discharge channel

1. A molding die for resin molding, the mold comprising:
a first die configured to hold a molded object; and
a second die configured to be clamped with the first die and having a cavity, wherein
the second die includes:
a pot that is communicably connected to a resin injection port provided on a bottom surface of the cavity, and where a resin material is contained;
an injection plunger that is advanced and retracted inside the pot to inject the resin material into the cavity via the resin injection port;
a resin reservoir that is communicably connected to a discharge port provided on the bottom surface of the cavity and where the resin material flown out of the cavity accumulates;
a suction hole that is connected to the resin reservoir and that is configured to suction air via the resin reservoir, through the discharge port; and
a switching plunger that is advanced and retracted inside the resin reservoir to switch between a mode for communicably connecting the suction hole to the discharge port, and a mode for blocking the suction hole.

2. The molding die for resin molding according to claim 1, wherein the resin injection port and the discharge port are provided in an outer periphery of the bottom surface of the cavity, and are provided at positions symmetrical to each other with respect to a center of the bottom surface of the cavity.

3. The molding die for resin molding according to claim 1, wherein the injection plunger and the switching plunger are advanced and retracted in a manner associated with each other.

4. The molding die for resin molding according to claim 1, wherein the switching plunger switches from the mode for communicably connecting the suction hole to the discharge port, to the mode for blocking the suction hole, in a manner associated with an operation of the injection plunger injecting the resin material, and then switches to a mode for pressing the resin material inside the cavity, together with the injection plunger.

5. The molding die for resin molding according to claim 1, wherein the second die includes:
an intermediate plate having the cavity, and provided with the resin injection port and the discharge port; and
a lower plate provided with the pot, the resin reservoir, and the suction hole.

6. The molding die for resin molding according to claim 1, wherein
the resin injection port is provided in a plurality, and the plurality of resin injection ports are connected to the pot via a resin supply channel, or
the discharge port is provided in plurality, and the plurality of discharge ports are connected to the resin reservoir via a resin discharge channel.

7. The molding die for resin molding according to claim 1, wherein
the pot is provided in plurality, and the plurality of pots are connected to the resin injection port via a resin supply channel, or
the resin reservoir is provided in plurality, and the plurality of resin reservoirs are connected to the discharge port by a resin discharge channel.

8. A resin molding apparatus comprising the molding die for resin molding according to claim 1.

9. A resin molded product manufacturing method using the molding die for resin molding according to claim 1, the resin molded product manufacturing method comprising:
a mold clamping step of clamping the first die and the second die;
a depressurizing step of suctioning air through the suction hole with a vacuum pump to depressurize the cavity while the suction hole and the discharge port are communicably connected to each other; and
a resin injection step of moving the injection plunger to inject the resin material into the cavity through the resin injection port, as well as moving the switching plunger to block the discharge port and the suction hole.

10. The resin molded product manufacturing method according to claim 9, further comprising, before the clamping step, placing a release film having through holes at positions corresponding to the injection port and the discharge port, respectively, provided on an inner surface including the bottom surface of the cavity, and placing pressing channel members for pressing peripheries of the respective through holes of the release film during clamping, and for forming communication channels communicably connecting the respective through holes to the cavity.
